(19) United States
(12) Patent Application Publication
(10) Pub. No.: US 2010/0013496 A1
(43) Pub. Date: Jan. 21, 2010

(54) Branch circuit black box

(75) Inventors: Jay R. Goetz, Deephaven, MN (US); Daniel J. Choudek, Prior Lake, MN (US)

Correspondence Address: Jay R. Goetz, 19610 Cottagewood Road, Deephaven, MN, 55331, US

(73) Assignees: Jay R. Goetz, Deephaven, MN (US); OnSite Engineering & Forensic Services, Inc., Prior Lake, MN (US)

(21) Appl. No.: 12/456,827

(22) Filed: Jun. 23, 2009

Related U.S. Application Data
(60) Provisional application No. 61/132,843, filed on Jun. 23, 2008.

(51) Int. Cl. H01H 31/02; G01R 31/00

(52) U.S. Cl. 324/555; 702/58

(57) ABSTRACT

A branch circuit black box for use in a building electrical system having service entrance, current protection switches (circuit breakers or fuses), and a power distribution system includes a plurality of sensors positioned adjacent to the distribution wires, wherein the sensor data is collected, analyzed and stored by a robust non volatile memory for the purpose of recovering state and operational characteristics of branch circuits after the incident has occurred in a building.

### CROSS-REFERENCE TO RELATED APPLICATION

The present application claims benefit of and priority to Provisional Patent Application Ser. No. 61/132,843 entitled BRANCH CIRCUIT BLACK BOX FILED Jun. 23, 2008, the entire contents of which are hereby incorporated by reference herein.

### BACKGROUND OF THE INVENTION

Information about the status of a building's electrical service (voltage and current distribution system) at the time of a fire or failure incident is often sought after the incident has occurred. The importance of this information is seen in the need to determine the cause and origin of fires within a building or property containing electrical distribution systems. Determining the history of the electrical branch circuit status at the time of the fire is described in the NFPA 921 document titled GUIDE FOR FIRE AND EXPLOSION INVESTIGATIONS. The methods described in this document are time consuming and can be inaccurate due to the damaging effects of extreme environmental attack or to suppression and overhaul operations by the attending Fire Department. Key information that could help in the analysis of the condition of the electrical systems just before and during the occurrence of a disastrous incident is often lost which makes it difficult for those investigating the scene to make sense of the remaining evidence.

Prior art suggests the use of detectors which sense current overloads, arcs, or high temperatures, and which even can shut off power to the affected branch circuits. U.S. Pat. No. 5,627,719 titled ELECTRICAL WIRING SYSTEM WITH OVERTEMP PROTECTION proposes to remove power when a certain temperature is reached. US Application Number 2007/0070568 titled ARC DETECTION CIRCUIT proposes an improved, more accurate method of detecting arcs. Both of these, however, do nothing to shed light on the origin and spread of a fire that does occur.

Prior art also suggests the use of fault diagnostic monitors for load centers or other equipment. U.S. Pat. No. 4,857,918 titled FAULT DIAGNOSTIC APPARATUS FOR ELECTYRIC APPLIANCE suggests the use of such a monitor for an air conditioner. U.S. Pat. No. 6,212,049 titled LOAD CENTER MONITOR FOR ELECTRICAL POWER LINES suggests the use of such a monitor for monitoring and analyzing circuit breakers.

What is needed and is not provided in prior art or available as a commercial product is a method of preserving certain state and operational characteristics of branch circuits at the time of a major catastrophic incident such as a fire, and which will maintain storage of the data after severe environmental stress has occurred and further, which will allow the retrieval of this data after some time has passed. This method should be robust and preferably independent of other systems in the house including power from those systems.

Energized electrical distribution systems are useful indicators in the investigation of a fire as well as major loss incidents such as flooding or mechanical damage. To date, investigators have relied on a time intensive technique called arc mapping to help them determine a point of origin for the fire. The theory is that an energized electrical circuit located in the area of origin for the incident will be affected first. Damage to its insulation will occur early in the incident timeline which will affect the integrity of the conductor isolation, resulting in an electrical arc. This in turn immediately trips a circuit breaker or blows a fuse which prevents further arcs from occurring on that particular circuit.

If multiple circuits travel through the area of origin, they also are affected and will loose their insulation in a similar manner. The result is a constellation of arc's, or a map with the area of origin at its center. The state of the circuit breakers is also useful information after an incident has occurred. To be useful in a typical room situation, certain elements are needed:
A matrix or grid of separate energized electrical circuits, preferably traveling at approximately right angles to each other.
Temperatures should preferably not reach more than about 1900 degF for copper wiring, 900 F for aluminum wiring. Above these temperatures, the wires will melt and obliterate whatever evidence was available at lower temperatures.
Some structure should remain in the room to hold the circuits in place
Separate operating circuit breakers on at least some of the circuits.
The circuits should not be heavily shielded from the heat of the developing fire, i.e. on the other side of a cinder block wall from the fire.

If these elements are not present, the analysis of data obtained from an arc mapping exercise may be compromised and the results uncertain. Even under ideal circumstances, there are issues with this approach:
Detail about how the fire spread, in time and direction of travel is unclear because the sequence and timing of the electrical arcs is not known.
Intense heat will often obliterate or mask the evidence of arcs by causing the wires to melt or severe.
Most service panels are un-locked and easily opened, allowing important information to be lost by humans manually resetting them, including the trip state of circuit breakers, pulling fuses, etc. The fire department will sometimes reset breakers as a means to removing power from circuits. Certain individuals will attempt arson to defraud insurance companies. They may tamper with evidence in the electrical circuit system to make it appear to be an accidental fire, and existing circuit elements can easily be tampered with (setting or resetting breakers or example).
Circuit breaker panels are resistant to heat to a point. Beyond that point, the settings of the breakers are lost as they melt and become un-recognizable.

### SUMMARY OF THE INVENTION

It is an object of the present invention to provide an electric branch circuit black box device which will avoid the problems noted above.

The addition of a branch circuit black box provides the investigator with sequence and/or time of the respective circuit arcs occurring which adds another dimension to the arc map data. Further, this device will contain a special event characterization memory which will be able to survive the destructive environment present. This in turn will enable better resolution of the area of origin in the analysis of the data.

A branch circuit black box for use in a building's electrical system having service entrance, current protection switches (circuit breakers or fuses), and a power distribution system in accordance with an embodiment of the present invention includes a plurality of sensors positioned adjacent to the distribution wires, wherein the sensor data is collected, analyzed and stored by a non volatile memory for the purpose of recovering time-of-incident state and operational information for resolution analysis after the incident has occurred in a building or system.

### BRIEF DESCRIPTION OF THE DRAWINGS

FIG. 1 is a top perspective view of a typical distribution of branch circuits emanating from service panel 1 near a service entrance 2 in a room 9 of a building where a fire has occurred. Branch circuit B3 4 has an electrical short circuit 5 near an outlet 6. Other branch circuits B1 3a, B2 3b, B4 3c are shown which proceed through this room to other areas of the structure.

FIG. 2 is an illustration of a branch circuit black box 7 in accordance with an embodiment of the present invention which detects electrical activity or status on branch circuits 3a,3b,3c, and 4 emanating from service panel 1. Outputs of the sensor modules 13 are connected to a processor 10 which is connected to a non volatile memory 11. Circuit breakers 8a, 8b, 8c, and 8d show tripped/not tripped status of example incident in FIG. 1.

FIG. 3 is a partial view of a branch circuit black box 7 showing more detail of one of the sensor modules 13 with individual sensors 13a, 13b, and 13c which are positioned close to individual conductors 14a, 14b, and 14c, and are connected to a processor (P) module to monitor the electrical parameters of interest required by the system.

FIG. 4 is a section view A of a sensor module showing sensors/amplifiers 13a, 13b, and 13c illustrated in a preferred position with respect to individual conductors 14a, 14b, and 14c which enables good electrical parameter measurement. The preferred orientation and alignment of the cable 12 is also shown.

### DETAILED DESCRIPTION OF PREFERRED EMBODIMENTS OF THE INVENTION

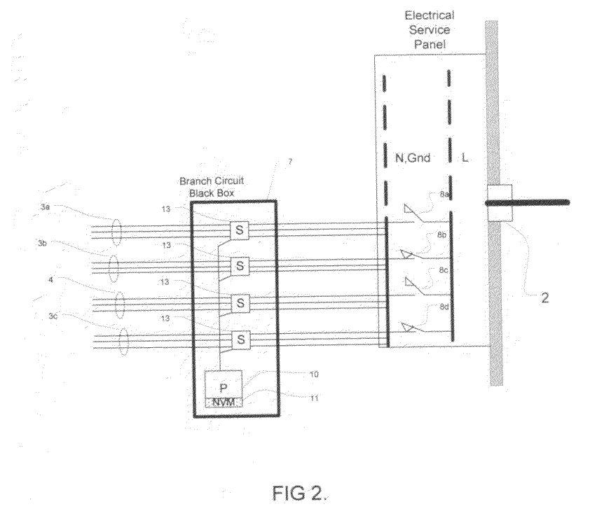

A branch circuit black box 7 for use in detecting, storing, and subsequently recovering the electrical activity, and operational state of an electrical system at the time of an incident involving damage to a facility is shown in FIG. 2. It is preferably located close to the main service panel 1, however the location of the branch circuit black box 7 is not limited to the vicinity of the service panel 1. It may be located in another room with the condition that access to the desired branch circuits is enhanced by this device being close to the central distribution point in that part of the facility, such as a sub-panel or a junction box.

In a preferred embodiment, the branch circuit black box includes a plurality of sensors 13 that detect the electrical activity or status on branch circuits emanating from the service panel 1. The electrical parameters recovered include, primarily, detection and storage of voltage, and time, however it is sometimes also desirable to capture current and temperature. A processor 10 is included which comprises primarily control logic and a non-volatile memory 11 that stores recent branch circuit 3a, 3b, 3c, and 4 activity detected by any of the sensors 13 wherein a change in the voltage triggers it's capture and storage, along with the time of the change. It is preferable to store the time when measurements are taken to establish sequential relationships between electrical activities occurring on the different branch circuits.

The operation of the branch circuit black box 7 is not limited to only capturing voltage during state transitions, and it may also synchronously capture the state of the voltage on the branch circuits 3a, 3b, 3c, and 4 on a periodic basis, wherein the period is shorter than expected electrical events normally occur and is typically from seconds to small fractions of a second.

Those skilled in the art will recognize that if the sensors 13 and processing 10 are sophisticated enough, additional computed results can be derived from these, including average or rms voltage or current, power, average power, and power factor.

Non-contact voltage sensing is well known in the art, commercial versions of these devices are available and need not be discussed here in detail. A method of voltage sensing is described in U.S. Pat. No. 4,804,922 titled VOLTAGE SENSOR, which discusses the sensing technique, and includes a filter to discriminate signal information in the frequency range of interest. Commercial detectors are available to measure electrostatic field or surface potential. U.S. Pat. No. 5,517,123 titled HIGH SENSITIVITY INTEGRATED MICROMECHANICAL ELECTROSTATIC POTENTIAL SENSOR describes a highly integrated and sensitive device for measuring voltage without contacting the object. Non-contact current sensing is also well known in the art and can be accomplished by using, for example, solid state Hall or Magnetoresistors as described in U.S. Pat. No. 4,539,520 titled REMOTE CURRENT DETECTOR and Number 4283643 titled HALL SENSING APPARATUS. As discussed in the prior art, these sensors 13 produce low voltage level signals which must be protected from system and environmental noise, and thus may include an amplifier to boost the signal level higher above the ambient noise of the chosen location for the branch circuit black box 7. The electronic functions 13, 10, and 11 shown in FIG. 2 can be implemented in various ways, including discrete electronics, separate modules, or integrated onto one monolithic substrate.

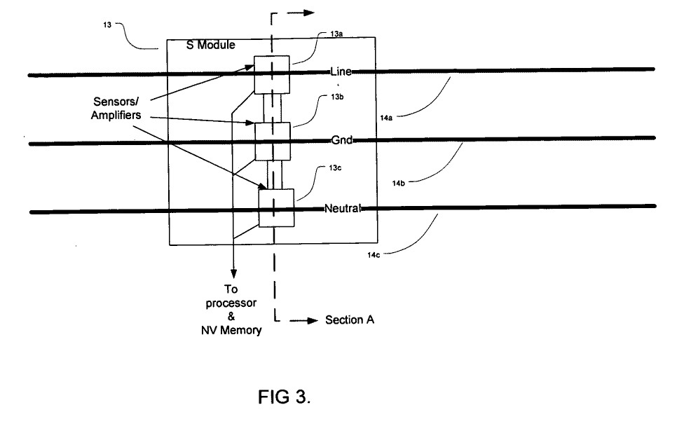

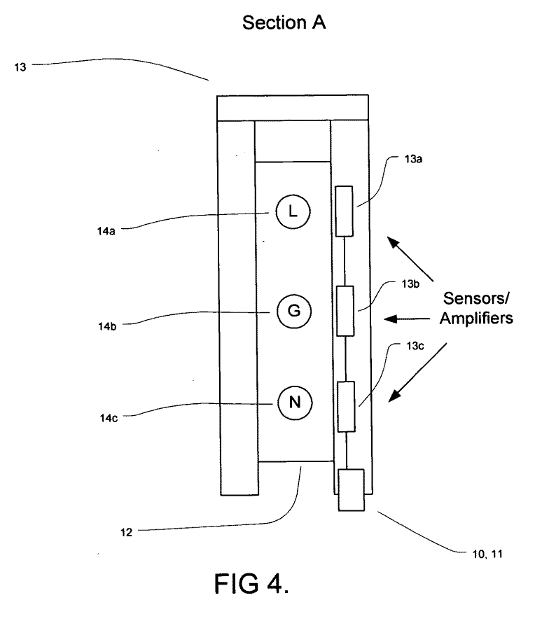

FIG. 3 shows Individual sensors 13a,13b, and 13c, part of sensor module S 13 being positioned close to individual conductors 14a, 14b, and 14c. For voltage measurement, 13a,13b, and 13c are sensitive to electrostatic fields. For current measurement, 13a,13b, and 13c are sensitive to magnetic fields. The sensors shown in FIG. 4 comprise a full detection capability. If detection of ground current or voltage is required, it with the sensor array for each branch. However, because the ground conductor usually carries no current, a sensor may not be needed in this position.

FIG. 4 shows a section view of the preferred embodiment of this invention. The sensor module 13 is sectioned to show approximate positioning of the sensors with respect to one of the branch circuit conductors 3a, 3b, 4, and 3d. The respective sensor 13a,13b, and 13c to wire 14a, 14b, and 14c spacing and the orientation of individual sensors is held fixed by the sensor module 13 housing in accordance with the optimal placement for detecting electrostatic and magnetic fields and with respect to the sensitive axes of the sensors used. As described above, detectors for non-contact measurement of these fields exist in the commercial marketplace. In another embodiment, the sensors are arrayed on both sides of the conductors to allow field measurements from more than one perspective. A ground plane may be added to provide reference for the measurement. In all of these cases however, the sensors must connect to the processor 10, which in turn is connected to the non volatile memory 11. Processors chosen for use in this device should be relatively low power and must have memory, sensor, and communication interfaces. Texas Instruments, for example, makes the MSP430 family of low power processors which is suitable for this application. A visit to their website at www.ti.com will yield information on applications similar to this one.

A key feature of this system is the ability to retain information in robust non volatile memory 11 which is connected to the processor 10. This memory will preferably be contained within in the Branch Circuit Black Box 7 and may actually be the same as the memory holding the operating system. However, because of its function during a catastrophic situation, the branch circuit black box 7 non volatile memory 11 may be exposed to severe heat and water and must maintain its storage function after such a situation. It must also be protected from mechanical damage and from tampering by individuals wishing to alter or destroy its contents. It may be desirable, for example, to encase the circuitry in heavy gauge steel or place it in a protected location where it is not easily removed and is protected from heat. The removal of the non volatile memory and extraction of information therein may be facilitated by use of special tools owned by investigators or by forensic engineers.

Even when power is interrupted or normal functionality is lost, the non volatile memory 11 will still contain the information originally recorded about the system. The memory is preferably solid state or magnetic in nature, however other methods may be used which do not require any power to sustain the contents. Battery hold-up of volatile memory may be a good choice if the battery itself can be made to be robust. Integrated (chip level) battery techniques can keep the memory powered for sufficient time duration to allow investigators time to recover it.

Normal operating power for the circuitry in the branch circuit black box 7 should be very small and many methods are available for providing it such as energy harvesting techniques, or long-life batteries such as lithium cells. Preferably, the circuitry is self-powering and harvests energy from the environment, wherein power is scavenged from energy in the fields of the wires themselves, and stored in batteries or capacitors. However, other methods may be used, including harvesting energy from photovoltaic cells sensitive to light.

It may be advantageous to use periodic wireless transmission of the data to a processor for central storage located amid several branch circuit black box sensor arrays. Texas Instruments makes wireless interface ICs which are useful for RF communication to nearby devices and which work well with their MSP430 processors.

### Branch Circuit Black Box Operation

In the operational examples discussed in this section, the branch circuit black box 7 must already have been in place when a fire or incident occurs. When the investigator visits the scene of an incident, the memory will already contains the electrical activity and status which occurred before, during, and shortly after the fire. If the extreme environment of a catastrophe damages the branch circuit black box 7 so as to make it non-functional, all events leading up to that time will still be safely recorded into non volatile memory 11.

Investigators will retrieve the non volatile memory 11 and forward it to engineers who will then remove it, interrogate it, and obtain the “history” of the incident for analysis of electrical activity and status at times surrounding the occurrence of the incident.

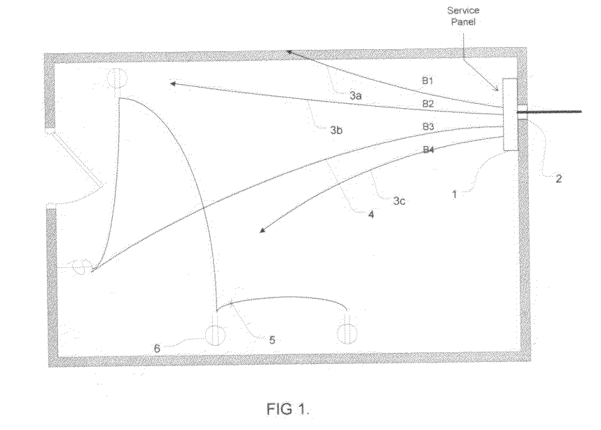

The following example shows how the preferred embodiment works in the case shown in FIG. 1. Short circuit faults have occurred on branch B3 4 and on branch B1 3a tripping their respective breakers and thus opening the paths to their respective loads. Note that branch B1 3a routes to elsewhere in the building which is not shown in FIG. 1. The Voltage and Current before and after the event, along with the time of the ‘trip’ are parameters that are continuously monitored, and can be stored in a memory record if they meet a threshold test. During manufacture or at installation time, the branches, parameters, and thresholds needed for each branch will be selected. An example data record as stored in non-volatile memory is shown below. Note that the voltage detector has sensed voltage of 120 Vrms before, then 0.1 Vrms after the incident, and the current detector has sensed 12 or 3 Arms before, and 0.05 Arms after the incident:

TABLE 1
Memory Record Example 1

| Branch | | | | | |
|---|---|---|---|---|---|
| circuit | | | | | |
| breaker | Time | Vbefore | Vafter | Ibefore | Iafter |
| B3 | 8:01:20 AM | 120 Vrms | .1 Vrms | 12 Arms | 0.05 Arms |
| B1 | 8:11:01 AM | 120 Vrms | .1 Vrms | 3 Arms | 0.05 Arms |

In this example the B3 branch circuit breaker 8c tripped at 8:01:20, followed by B1 branch circuit breaker 8a trip at 8:11:01. The activity and the time of the activity are thus captured and stored in the memory. Capturing and storing of the branch circuit electrical activity may be asynchronously triggered by either voltage or current transitions on particular branches, however other detected parameters reaching an preset threshold value can cause the capture of data as well, such as temperature, conductivity, phase relationship, harmonic noise, or any other electrical property which may signify the occurrence of an incident (fire, flood, loss of air flow to equipment, presence of explosive gas, failure etc).

In a second embodiment, only the discrete energized state information is required and measured analog values are not required. During manufacture or at installation time, the branches and desired state configuration is pre-determined, along with the state transition threshold to trigger storage. An example memory record is shown below:

TABLE 2
Memory Record Example 2

| Branch | | | |
|---|---|---|---|
| circuit | | | |
| breaker | Time | State_before | State_after |
| B3 | 8:01:20 AM | Closed | Open |
| B1 | 8:11:01 AM | Closed | Open |

In this example, the branch B3 circuit breaker 8c tripped at 8:01:20, followed by branch B1 circuit breaker 8a trip at 8:11:01, but only the discrete state information is retained in the memory. The trigger and threshold applied here can be, for example, the opening of more than one circuit breaker, separated by more than 0.1 second, and less than 30 min of time. This embodiment is simpler than example 1 due to only requiring a discrete time event monitor and thus can be lower in cost than the first embodiment.

In a third embodiment, the temperature at the Branch Circuit Black Box is recorded along with the other parameter information:

TABLE 3
Memory Record Example 3

| Branch | | | | | | |
|---|---|---|---|---|---|---|
| circuit | | | | | | |
| breaker | Time | Vbefore | Vafter | Ibefore | Iafter | Temperature |
| B3 | 8:01:20 AM | 120 Vrms | .1 VAC | 21 Arms | 21 Arms | 160 F. |
| B1 | 8:01:20 AM | 120 Vrms | .1 VAC | 20 Arms | 20 Arms | 160 F. |

In this example, the temperature at the conductors where the branch circuit black box 7 is located exceeded a threshold of 160 F, which triggered the memory to read data. However, none of the breakers has tripped yet.

In a fourth embodiment, parameter and/or state information can be recorded along with time in a “continuous loop” fashion. For example, data is simply streamed into the memory which functions as a FIFO with continuous looping capability . . . never stopping the recording of parameter information and time of capture until either commanded to, or until some significant pre-determined state change occurs (loss of more than 1 branch circuit, temperatures above 100 F, currents exceeding 30 A, etc).

Example memory records for such a system are shown below, with state changes occurring on branch B1 3a at time 25,2019 seconds and on branch B3 4 at 25,2020 seconds, where time is kept as a count of seconds. The advantage of this system is that the memory controls and time-keeping requirements of this system are simplified since an external trigger is not required, thus not requiring any special circuitry or threshold setting. For this example, the memory store trigger is dependant upon the energized/de-energized branch state changes, and can, for example be more than 2 circuit breakers tripping within 5 minutes of each other, but greater than 0.5 seconds. It is also possible, but not necessary for this embodiment to function, for an internal temperature operated switch to open at 150 F, which will halt the memory access after the last record is written:

TABLE 4
Memory Record Example 4

| Branch | | | | |
|---|---|---|---|---|
| circuit | | | | |
| breaker | Time | State_before | State_after | Temperature > 150 F. |
| B1 | 25, 2018 | Closed | Closed | No |
| B2 | 25, 2018 | Closed | Closed | No |
| B3 | 25, 2018 | Closed | Closed | No |
| B4 | 25, 2018 | Closed | Closed | No |
| B1 | 25, 2019 | Closed | Closed | No |
| B2 | 25, 2019 | Closed | Closed | No |
| B3 | 25, 2019 | Closed | Open | No |
| B4 | 25, 2019 | Closed | Closed | No |
| B1 | 25, 2020 | Closed | Open | Yes |
| B2 | 25, 2020 | Closed | Closed | Yes |
| B3 | 25, 2020 | Closed | Open | Yes |
| B4 | 25, 2020 | Closed | Closed | Yes |

In variations of embodiment four, different properties can be used to force termination of memory access in anticipation of possible harsh environment.

In a fifth embodiment, environmental hardening of the device may be implemented by some combination of heat shielding, hermetic packaging, use of high temperature substrates, special coatings, and/or positioning it in a location where it is not exposed to any expected harsh environments, for example, embedded in concrete or cinder block and covered by a metal plate. This will reduce risk of data loss due to exposure to hostile conditions such as high temperatures. It is also possible for the non-volatile memory to be located in a protected position, separate from the rest of the circuitry. Another option is for the non-volatile memory to be located in another system such as an energy management, HVAC control, or alarm panel. In these cases, a more robust memory communication bus/connection will be required and a wireless link may be preferable.

In a sixth embodiment, the Branch Circuit Black Box is used in other systems or subsystems, wherein the system's power feed is available and accessible at a single point and then distributes throughout the system. Examples include an aircraft, automobiles, or watercraft, but also may include any system or device containing a network of power arranged as branches or in a star distribution such as appliances, machines, or other devices. It is often desirable and useful to know how the power state or usage changed within a complex system or structure just prior to a problem or incident occurring. The branch circuit black box 7 can provide this information which can be useful in troubleshooting problems and resolving failures.

Use in spacecraft is also envisioned. In these cases, the properties which will trigger the branch circuit black box 7 to store information may include radiation, velocity, altitude, roll-rate, loss of navigation, loss of control, and many other possibilities.

In all of these embodiments, the key information retained, and stored into non volatile memory is information about the branch circuit states including the unique sequence and the time of the “change of state” on each branch circuit. Other results could be calculated or derived from inputs available near the service entrance or the panel and also stored in the non-volatile memory. Some of these might include:
1. Service entrance voltage and current (sags, outages and surges)
2. Service entrance voltage and current imbalance (neutral loss)
3. Voltage surge events . . . due to lightning or other disturbance
4. System and Branch Power factor (harmonic distortion, high reactive power)
5. System and Branch Power (high impedance faults and detectable appliance failures)
6. System and Branch EMI, signal characteristics (noise, interference)
7. Communicating across power lines (recovery of digital signals)

1. A branch circuit black box for use in saving and recovering the electrical activity and state of an electrical system at the time of an incident involving significant damage to a facility, structure, or equipment, including:
A plurality of sensors positioned near branch circuits at the point where they are close to, but just outside of the electric service panel;
means for detection of branch circuit electrical activity and status, and means for controlling analysis, capture and storage of said electrical detections from the sensors, and
means for subsequently recovering the data for further processing.

2. The device of claim 1, wherein the sensors are each disposed adjacent to individual wires of the branch circuit for purposes of measuring the electrical parameters of the circuit comprised of:
A sensor located adjacent to the Line voltage conductor,
a sensor located adjacent to the ground conductor, and
a sensor located adjacent to the Neutral conductor.

3. The device of claim 2, wherein:
the plurality of sensors detect a significant combination of electrostatic or magnetic fields in the space surrounding the wires which represents activity or status of the circuit, wherein
the significance may be a certain value reached or the absence or presence of detected data, and
the detected data is captured electronically in preparation for possible storage.

4. The device of claim 3, wherein:
the captured sensor data is the ‘state’ of the sensor data on one or more circuits wherein,
the state is synchronously sampled and stored into non volatile memory.

5. The device of claim 3, wherein:
the captured sensor data itself asynchronously triggers its storage into non volatile memory by occurrence of a significant transition or repeated transitions of said sensor data value or by the loss of it on one or more circuits, wherein
the trigger threshold may be established at the time of manufacture or in the field.

6. The device of claim 4 wherein:
the storage of sensor data into non-volatile memory is recorded in a “continuous loop” fashion, and
the memory is configured to do continuous recording of sensor data and time of capture until either commanded to stop, or until some significant sensor data transition or time lapse occurs.

7. The device of claim 3, wherein:
the trigger parameter includes pressure, humidity, conductivity, phase relationship, harmonic noise, or any other property which aids in the subsequent resolution of a catastrophic incident at or near one or more branch circuits.

8. The device of claim 3, wherein:
the sensors communicate data to a processor within the branch circuit black box which controls capture, timing, analysis and storage of data from the sensors, which may include:
any combination of parameters important to understanding how the incident happened, including voltage, current, temperature, and
the sensor data is processed, selecting it for storage in efficient form, and
the processed sensor data is stored in a robust, environmentally hardened, non-volatile memory along with the time of capture.

9. The device of claim 3 wherein environmental hardening of the device is comprised of shielding, hermetic packaging, special substrates or coatings, embedding/encasing the device, and/or positioning it in a location where it is less exposed to potential harsh environments in order to prevent loss of data.

10. The device of claim 2 wherein the ground conductor sensor is not present.

11. The device of claim 1 wherein:
The non volatile memory is robust and may contain security features which protect its contents from tampering.
the non volatile memory is ruggedized and retrievable, either along with the branch circuit black box or separable from it, and
the non volatile memory can be independently interrogated to recover its contents.

12. The device of claim 2 wherein the branch circuit black box operates independently in function and connection from other systems in the house, and further is self-powered

13. The device of claim 2 wherein the sensor data is periodically communicated to a central data collection processor via RF wireless communication.
